(19) United States
(12) Patent Application Publication
(10) Pub. No.: US 2026/0194563 A1
(43) Pub. Date: Jul. 9, 2026

(54) SYSTEM AND METHOD FOR DETECTING MISLABELING OF ELECTRIC VOLTAGE PHASE LABELS IN A THREE PHASE ELECTRIC POWER DISTRIBUTION NETWORK

(71) Applicant: Kansas State University Research Foundation, Manhattan, KS (US)

(72) Inventors: James Ranjith Kumar Rajasekaran, Manhattan, KS (US); Bala Natarajan, Manhattan, KS (US); Anil Pahwa, Manhattan, KS (US)

(21) Appl. No.: 19/132,132

(22) PCT Filed: Nov. 22, 2023
(86) PCT No.: PCT/US2023/080873

§ 371 Date: May 22, 2025

Related U.S. Application Data
(60) Provisional application No. 63/427,532, filed on Nov. 23, 2022.

(51) Int. Cl. G01R 25/00

(52) U.S. Cl. CPC G01R 25/005

(57) ABSTRACT

A method for determining one or more mislabeled phases of the voltage at one or more laterals and customer points in a three phase power distribution network comprises receiving data indicating a plurality of electrical connections among components of the three phase power distribution network including a plurality of buses: receiving a plurality of sensor data values including voltage measurements and power measurements for a first portion of the buses; converting each voltage measurement to a voltage phasor; converting each power measurement to a current phasor; assigning values of voltage, voltage deviation, and current to a second portion of the buses where sensor data values are unavailable; calculating a residual between a plurality of network values and a plurality of expected values; and detecting whether any phases are mislabeled in the three phase power distribution network using a mathematical relationship that includes a residual term and a chi squared term.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/427,532; titled “SYSTEM AND METHOD FOR DETECTING MISLABELING AND FALSE DATA INJECTION OF ELECTRIC VOLTAGE PHASE LABELS IN A THREE PHASE ELECTRIC POWER DISTRIBUTION NETWORK”, and filed Nov. 23, 2022. The Provisional application is hereby incorporated by reference, in its entirety, into the current patent application.

### STATEMENT REGARDING FEDERALLY-SPONSORED RESEARCH OR DEVELOPMENT

This invention was made with Government support under Contract No.: DE-EE0008767 awarded by the United States Department of Energy, Office of Energy Efficiency and Renewable Energy (EERE), Solar Energy Technologies Office. The Government has certain rights in the invention.

### FIELD OF THE INVENTION

Embodiments of the current invention relate to systems and methods that determine electric voltage phase labels in a three phase electric power distribution network.

### BACKGROUND

Alternating current (AC) electric voltage is generated to have a periodic waveform. Three phase electric voltage provides three AC electric voltage waveforms, with each waveform having a phase that is 120 degrees out of phase with the other two waveforms—thus providing three different voltage phases which are generally labeled “A”, “B”, and “C”. Referring to FIG. 1, electric power distribution networks often utilize the three phase electric voltage configuration when delivering electric power from a network distribution point, such as a substation, to a plurality of customers, such as residential houses, office buildings, stores, schools, and the like. The substation provides three phase voltage to a plurality of feeders, which in turn, provide three phase, two phase, or single phase voltage to a plurality of laterals, which provide single phase voltage (A, B, or C) to the customers. The feeders and laterals may include components like transformers, switches, and so forth which help adjust the power delivered to the customers. The network may also include distributed energy resources, such as rooftop solar cells, local wind turbines, and the like, which increase the complexity of the network.

Knowing the phase of the voltage at each of the lateral and customer points can allow a utility company to balance the customers among the three phases as well as accurately determine the capacity of the network to provide sufficient power. However, over time, knowledge of the specific phase at each of the lateral and customer points is lost due to restoration, reconfiguration, maintenance, addition of customer loads and distributed energy resources, and other changes which are not recorded—leaving the utility company with reduced or limited knowledge to properly operate the network. In addition, the phase at some of the lateral and customer points may be mislabeled which can cause the same problems as the phase label being unknown.

### SUMMARY OF THE INVENTION

Embodiments of the current invention address one or more of the above-mentioned problems and provide methods, computing devices, and computer-readable media for determining one or more mislabeled phases of the voltage at one or more laterals and/or customer points in a three phase power distribution network.

A method comprises receiving data indicating a plurality of electrical connections among components of the three phase power distribution network including a plurality of buses; receiving a plurality of sensor data values including voltage measurements, power measurements, or both for a first portion of the buses; converting each voltage measurement to a voltage phasor; converting each power measurement to a current phasor; determining a bus hybrid matrix including a bus impedance matrix and a bus admittance matrix; assigning values of voltage, voltage deviation, and/or current to a second portion of the buses where sensor data values are unavailable utilizing data derived from the bus hybrid matrix; calculating a residual between a plurality of network values and a plurality of expected values; and detecting whether any phases are mislabeled in the three phase power distribution network using a mathematical relationship that includes a residual term and a chi squared term.

A computing device comprises a processing element configured or programmed to: receive data indicating a plurality of electrical connections among components of the three phase power distribution network including a plurality of buses; receive a plurality of sensor data values including voltage measurements, power measurements, or both for a first portion of the buses; convert each voltage measurement to a voltage phasor; convert each power measurement to a current phasor; determine a bus hybrid matrix including a bus impedance matrix and a bus admittance matrix; assign values of voltage, voltage deviation, and/or current to a second portion of the buses where sensor data values are unavailable utilizing data derived from the bus hybrid matrix; calculate a residual between a plurality of network values and a plurality of expected values; and detect whether any phases are mislabeled in the three phase power distribution network using a mathematical relationship that includes a residual term and a chi squared term.

A non-transitory computer-readable medium having stored thereon software instructions for determining one or more mislabeled phases of the voltage at one or more laterals and/or customer points in a three phase power distribution network that, when executed by a processing element, causes the processing element to: receive data indicating a plurality of electrical connections among components of the three phase power distribution network including a plurality of buses; receive a plurality of sensor data values including voltage measurements, power measurements, or both for a first portion of the buses; convert each voltage measurement to a voltage phasor; convert each power measurement to a current phasor; determine a bus hybrid matrix including a bus impedance matrix and a bus admittance matrix; assign values of voltage, voltage deviation, and/or current to a second portion of the buses where sensor data values are unavailable utilizing data derived from the bus hybrid matrix; calculate a residual between a plurality of network values and a plurality of expected values; and detect whether any phases are mislabeled in the three phase power distribution network using a mathematical relationship that includes a residual term and a chi squared term.

### BRIEF DESCRIPTION OF THE DRAWING FIGURES

Embodiments of the current invention are described in detail below with reference to the attached drawing figures, wherein:

FIG. 1 is a schematic block diagram of a three phase power distribution network which includes at least one substation, a plurality of feeders, a plurality of laterals, and a plurality of customers;

FIG. 2 is a view of a plurality of components of a computing device constructed in accordance with various embodiments of the invention;

FIG. 3 is a schematic block diagram of the electronic components of the computing device; and

FIG. 4 is a flow diagram listing at least a portion of the steps of a method for determining one or more mislabeled phases of the voltage at one or more laterals and/or customer points in a three phase power distribution network.

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE EMBODIMENTS

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

In the following description, the word “voltage” may be used to describe electric voltage, the word “current” may be used to describe electric current, and the word “power” may be used to describe electric power.

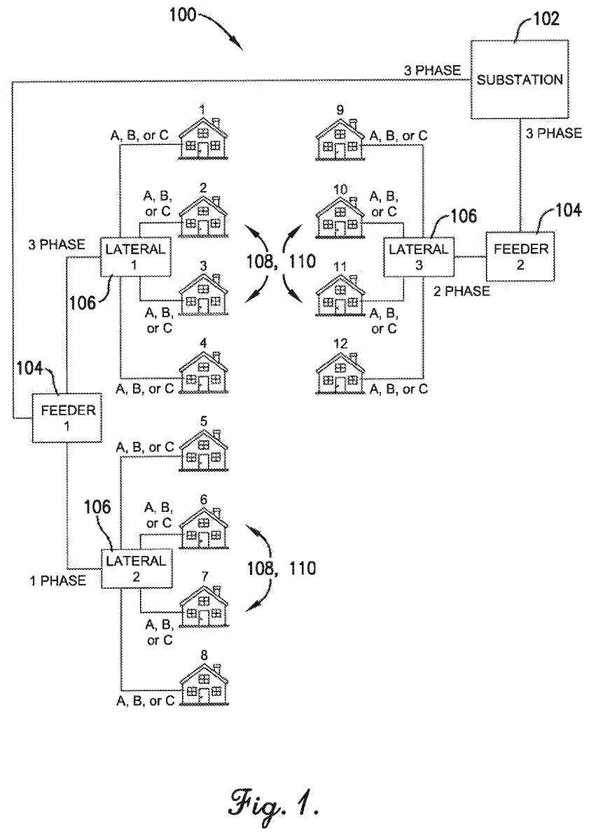

Referring to FIG. 2, a computing device 10, constructed in accordance with various embodiments of the current invention, for determining a plurality of mislabeled phases of the phase of the voltage at a plurality of laterals and/or customer points in a three phase power distribution network 100. The three phase power distribution network 100, as shown in FIG. 1, may cover a portion of a city, a city, a region, or so forth. The three phase power distribution network 100 is formed by a plurality of nodes electrically connected to one another by lines and may include at least one substation 102, a plurality of feeders 104, a plurality of laterals 106, and a plurality of customers 108, among others, wherein each of these components is one of the nodes. The substation 102 may include components such as transformers, switches, circuit breakers, relays, and the like. Each feeder 104 and each lateral 106 may include one or more transformers, switches, and the like. The customers 108 consume power and may include residential houses, office buildings, stores, schools, and the like. (Some customers may also have distributed energy resources, which source electric power.) The substation 102 provides three phase voltage to the feeders 104, which in turn, provide three phase, two phase, or single phase voltage to the laterals 106, which provide single phase voltage to the customers 108. (In some instances, one or more customers 108 may receive three phase voltage.) The three phase power distribution network 100 may further include a plurality of buses, each of which connects one feeder 104 to a plurality of laterals 106 or one lateral 106 to a plurality of customers 108. The exemplary three phase power distribution network 100 includes one substation 102, two feeders 104, a first lateral 106 that receives three phases of voltage, a second lateral 106 that receives one phase of voltage, and a third lateral 106 that receives two phases of voltage. The computing device 10 determines the node phase label, A, B, or C, at each lateral 106 and customer 108.

At least a portion of the customers 108 and the electric power distribution components, such as the substation 102, the feeders 104, and the laterals 106, has a sensor 110, such as a scalar sensor, which measures or determines, at the least, a magnitude of the voltage at each site. In some embodiments, the sensor 110 may also include a phasor measurement unit (PMU) which measures or determines the magnitude and an angle of the voltage at the site. In other embodiments, the sensor 110 may also measure or determine real and/or reactive power consumed by the customer 108. In addition, the sensor 110 includes, or is in communication with, circuitry or components configured to communicate or transmit any measured or determined data including the voltage magnitude, along with the voltage angle, and the real and/or reactive power as a sensor data value to the computing device 10. The sensor data value may be communicated or transmitted wirelessly or using wired networks. For example, the sensor data value may be communicated or transmitted via the Internet, cloud networks, telecommunication networks, or the like. The sensor data values are transmitted on a periodic basis. For example, the sensor data values may be transmitted several times per day, such as once every one or two hours, although a higher or a lower frequency may be implemented as well. Furthermore, in some embodiments, each sensor data value may be accompanied by an identification code or number, a location, such as an address or a geolocation, or both.

An exemplary sensor 110 may be embodied by a supervisory control and data acquisition (SCADA) sensor which is configured or operable to provide one sensor data value at a rate ranging from 1 per second to 1 per minute. A micro PMU sensor 110 may provide 512 sensor data values for a 60 hertz (Hz) frequency for a total output of 30,720 sensor data values per second. The sensor 110 may be configured, however, to transmit a plurality of sensor data values during a single transmission that is transmitted once every 1-2 hours.

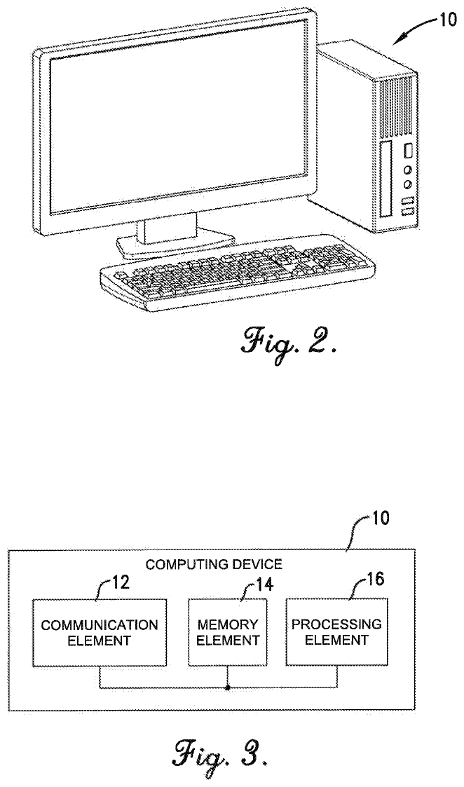

The computing device 10, as shown in FIG. 2, may be embodied by one or more servers, high performance computers, workstation computers, desktop computers, laptop computers, palmtop computers, notebook computers, tablets or tablet computers, and so forth. The computing device 10, as shown in FIG. 3, includes a communication element 12, a memory element 14, and a processing element 16. The computing device 10 may also include a display or monitor, a keyboard, a mouse, and other components not discussed herein.

The communication element 12 generally allows the computing device 10 to communicate with other computing devices, external systems, networks, and the like. The communication element 12 may include signal and/or data transmitting and receiving circuits, such as antennas, amplifiers, filters, mixers, oscillators, digital signal processors (DSPs), and the like. The communication element 12 may establish communication wirelessly by utilizing radio frequency (RF) signals and/or data that comply with communication standards such as cellular 2G, 3G, 4G, Voice over Internet Protocol (VoIP), LTE, Voice over LTE (VoLTE), or 5G, Institute of Electrical and Electronics Engineers (IEEE) 802.11 standard such as WiFi, IEEE 802.16 standard such as WiMAX, Bluetooth™, or combinations thereof. In addition, the communication element 12 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 12 may establish communication through connectors or couplers that receive metal conductor wires or cables which are compatible with networking technologies such as ethernet. In certain embodiments, the communication element 12 may also couple with optical fiber cables. The communication element 12 may be in electronic communication with the memory element 14 and the processing element 16.

The memory element 14 may be embodied by devices or components that store data in general, and digital or binary data in particular, and may include exemplary electronic hardware data storage devices or components such as read-only memory (ROM), programmable ROM, erasable programmable ROM, random-access memory (RAM) such as static RAM (SRAM) or dynamic RAM (DRAM), cache memory, hard disks, floppy disks, optical disks, flash memory, thumb drives, universal serial bus (USB) drives, solid state memory, or the like, or combinations thereof. In some embodiments, the memory element 14 may be embedded in, or packaged in the same package as, the processing element 16. The memory element 1A may include, constitute, or embody, a non-transitory “computer-readable medium”. The memory element 14 may store the instructions, code, code statements, code segments, software, firmware, programs, applications, apps, services, daemons, or the like that are executed by the processing element 16. The memory element 14 may also store data that is received by the processing element 16 or the device in which the processing element 16 is implemented. The processing element 16 may further store data or intermediate results generated during processing, calculations, and/or computations as well as data or final results after processing, calculations, and/or computations. In addition, the memory element 14 may store settings, text data, documents from word processing software, spreadsheet software and other software applications, sampled audio sound files, photograph or other image data, movie data, databases, and the like.

The processing element 16 may comprise one or more processors. The processing element 16 may include electronic hardware components such as microprocessors (single-core or multi-core), microcontrollers, digital signal processors (DSPs), field-programmable gate arrays (FPGAs), analog and/or digital application-specific integrated circuits (ASICs), or the like, or combinations thereof. The processing element 16 may generally execute, process, or run instructions, code, code segments, code statements, software, firmware, programs, applications, apps, processes, services, daemons, or the like. The processing element 16 may also include hardware components such as registers, finite-state machines, sequential and combinational logic, configurable logic blocks, and other electronic circuits that can perform the functions necessary for the operation of the current invention. In certain embodiments, the processing element 16 may include multiple computational components and functional blocks that are packaged separately but function as a single unit. In some embodiments, the processing element 16 may further include multiprocessor architectures, parallel processor architectures, processor clusters, and the like, which provide high performance computing. The processing element 16 may be in electronic communication with the other electronic components of the computing device 10 through serial or parallel links that include universal busses, address busses, data busses, control lines, and the like. In addition, the processing element 16 may include ADCs to convert analog electronic signals to (streams of) digital data values and/or digital to analog converters (DACs) to convert (streams of) digital data values to analog electronic signals.

The processing element 16 may be operable, configured, or programmed to perform the following functions, processes, methods, or algorithms by utilizing hardware, software, firmware, or combinations thereof. Other components, such as the communication element 12 and the memory element 14 may be utilized as well.

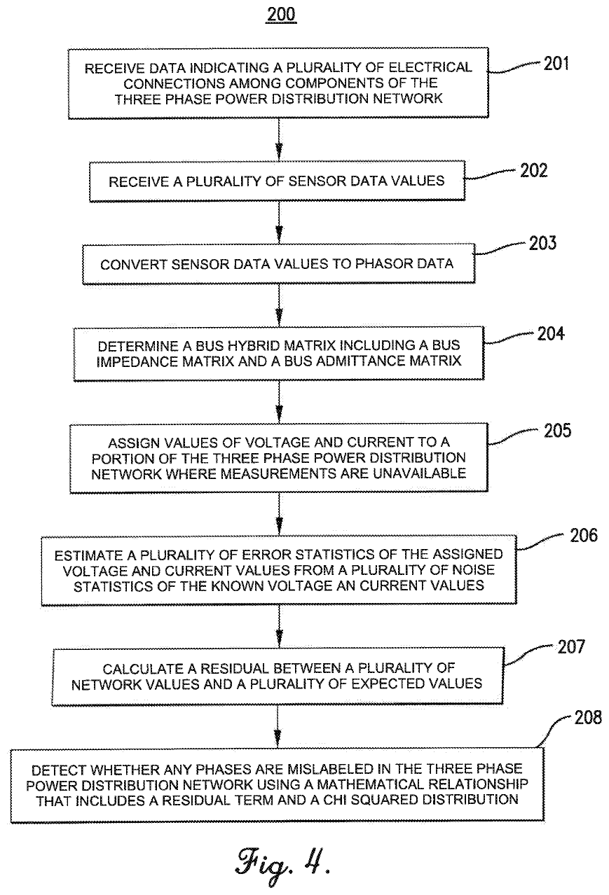

A flow diagram illustrating steps of a method 200 for determining one or more mislabeled phases of the voltage at one or more laterals and/or customer points in the three phase power distribution network 100 is shown in FIG. 4. Variations to the steps may be performed. The steps may be performed in the order shown in FIG. 4, or they may be performed in a different order. Furthermore, some steps may be performed concurrently as opposed to sequentially. In addition, some steps may be optional or may not be performed. Also, at least a portion of the steps may be implemented as instructions, code, code segments, code statements, a program, an application, an app, a process, a service, a daemon, or the like, and may be stored on a computer-readable storage medium, such as the memory element 1A.

Referring to step 201, data is received indicating a plurality of electrical connections among components of the three phase power distribution network 100. The data includes a schematic list, a node list, a topology list, or similar documentation that identifies the electrical connections of all of the nodes of the three phase power distribution network 100. The electrical connection scheme of the three phase power distribution network 100 may be stored in an array, a database, or similar data structure in the memory element 14.

Referring to step 202, a plurality of sensor data values is received. Typically, the processing element 16 receives one sensor data value from each sensor 110 at a frequency of several times per day. For example, the processing element 16 may receive one sensor data value from each sensor 110 once every one or two hours. Furthermore, it is possible that one or more of the sensors 110 transmits sensor data values less often. In addition, there is a plurality of nodes, i.e., laterals and/or customer points, for which there is no sensor 110, or the sensor 110 does not transmit any data.

The sensor data value includes a magnitude value of the voltage (voltage measurement) and a real power injection at the customer site. In various embodiments, the sensor data value may additionally, or alternatively, include a voltage angle, a real power value, a reactive power value, or the like, or combinations thereof. In addition, each sensor data value may be accompanied by an identifier that includes an identification code or number, a location, such as an address or geolocation, or both. Each sensor data value and its associated identifier may be stored in an array, a database, or similar data structure in the memory element 14.

Referring to step 203, the sensor data values are converted to phasor data. Each voltage magnitude is converted to a voltage phasor, and each real power injection is converted to a current phasor. For transforming the voltage magnitudes into equivalent voltage phasors it is assumed that in distribution systems, the voltage angle difference between the buses are negligible. Such an assumption is quite valid as the feeders 104 in the three phase power distribution network 100 are not very long and tend to have low electrical reactance to electrical resistance (X/R) ratio. Based on this assumption, the angular difference corresponding to its phase can be used with the voltage magnitude value,

$$\vert {v}_{i}^{ϕ} \vert ,$$

measured at phase φ of bus i to obtain its equivalent voltage phasor as:

$${v}_{i}^{ϕ} = \vert {v}_{i}^{ϕ} \vert < {δ}^{ϕ} \qquad EQ . 1$$

wherein δ=0 degrees, if the phase φ label is A; δ=−120 degrees, if the phase label φ is B; and δ=120 degrees, if the phase φ label is C.

Each real power injection is converted to a current phasor, utilizing a derived reactive power and the voltage phasor. The power factor of the loads in the three phase power distribution network 100 tend to be consistent and hence it is assumed to be constant with a value: cos θ. With this assumption, an approximate value of the reactive power,

$${q}_{i}^{ϕ} ,$$

can be recovered using the real power measurement

$${p}_{i}^{ϕ} ,$$

at phase φ of bus i as:

$${q}_{i}^{ϕ} = {p}_{i}^{ϕ} tan θ \qquad EQ . 2$$

With this recovered approximate voltage phasor,

$${v}_{i}^{ϕ}$$

along with the values of real power injection,

$${p}_{i}^{ϕ} ,$$

and reactive power injection,

$${q}_{i}^{ϕ} ,$$

the approximate value of current injection (i) at phase φ of bus i can be obtained as:

$${i}_{i}^{ϕ} = {( \frac{{p}_{i}^{ϕ} + {jq}_{i}^{ϕ}}{{v}_{i}^{ϕ}} )}^{*} \qquad EQ . 3$$

Referring to step 204, a bus hybrid matrix is computed, which includes a combination of a bus impedance matrix Z and a bus admittance matrix Y. For the three phase power distribution network 100, let S be the set of nodes in the reference bus corresponding to all its three phases and B be the set of all the remaining nodes in the three phase power distribution network 100 excluding the nodes corresponding to the reference bus. It is to be noted that to handle unbalanced portions of the three phase power distribution network 100, each phase of a given bus is considered as a node. Consider that vEC^{|B|} and i∈C^{|B|}, such that v and i are the complex vectors of nodal voltages and current injections at all nodes given by set B. Similarly, v_{S}∈C^{|S|}, such that vₛ is the voltage at the nodes in the reference bus given by set S. With these definitions, the relationship between the current injections and nodal voltages can be written as:

$$i = {Y}_{S} \cdot {v}_{S} + Y \cdot v \qquad EQ . 4$$

wherein Y and Ys are the block forms of the nodal admittance matrix (Y) for the nodes given by set B and S respectively. The expression given in EQ. 4 can be written in linear form as:

$$Z \cdot i = Δ v \qquad EQ . 5$$

wherein the voltage deviation Δv=Z·Y_{S}·v_{S}+v and Z=Y⁻¹ is the nodal impedance matrix with S as the reference.

For the three phase power distribution network 100, the set of buses at which the bus voltage phasor deviations, Δv, and the current injection phasors, i, are available is given by set K. The set of buses at which the bus voltage phasor deviations, Δv, and the current injection phasors, i, are unavailable is given by set U, which is the complement of set K. With this definition, the relation between voltage deviations and the current injections that is given in EQ. 5 can be rewritten as:

$$[ \begin{matrix}{Z}_{KK} & {Z}_{KU} \\ {Z}_{UK} & {Z}_{UU}\end{matrix} ] [ \begin{matrix}{i}_{K} \\ {i}_{U}\end{matrix} ] = [ \begin{matrix}Δ {v}_{K} \\ Δ {v}_{U}\end{matrix} ] \qquad EQ . 6$$

wherein the bus impedance matrix is:

$$Z = [ \begin{matrix}{Z}_{KK} & {Z}_{KU} \\ {Z}_{UK} & {Z}_{UU}\end{matrix} ] \qquad EQ . 7$$

The bus admittance matrix (excluding the slack bus) can be obtained from bus impedance matrix as Y=Z⁻¹ as shown:

$$[ \begin{matrix}{Y}_{KK} & {Y}_{KU} \\ {Y}_{UK} & {Y}_{UU}\end{matrix} ] [ \begin{matrix}Δ {v}_{K} \\ Δ {v}_{U}\end{matrix} ] = [ \begin{matrix}{i}_{K} \\ {i}_{U}\end{matrix} ] \qquad EQ . 8$$

wherein the bus admittance matrix is:

$$Y = [ \begin{matrix}{Y}_{KK} & {Y}_{KU} \\ {Y}_{UK} & {Y}_{UU}\end{matrix} ] \qquad EQ . 9$$

Solving EQ. 6 for Δv_{U}, solving EQ. 8 for i_{U}, and performing substitution of various terms yields:

$${H}^{v} Δ {v}_{u} + {H}^{i} {i}_{U} = [ \begin{matrix}{G}^{v} \cdot Δ {v}_{K} \\ {G}^{i} \cdot {i}_{K}\end{matrix} ] \qquad EQ . 10$$

wherein the Jacobian matrices H and the gaussian matrices G are given as:

$${H}^{v} = [ \begin{matrix}I \\ {Y}_{UK} {Y}_{KK}^{- 1} {Y}_{{KU}^{-}} {Y}_{UU}\end{matrix} ] \qquad EQ . 11$$

$${H}^{i} = [ \begin{matrix}{Z}_{UK} {Z}_{KK}^{- 1} {Z}_{{KU}^{-}} {Z}_{UU} \\ I\end{matrix} ] \qquad EQ . 12$$

$${G}^{v} = {Z}_{UK} {Z}_{KK}^{- 1} \qquad EQ . 13$$

$${G}^{i} = {Y}_{UK} {Y}_{KK}^{- 1} \qquad EQ . 14$$

Referring to step 205, the unavailable values of voltage, voltage deviation, and/or current for the portion of the three phase power distribution network 100 lacking data are imputed, estimated, substituted, or assigned by making use of the sensor data values that are known. Assignment of values to the unavailable measurements utilizes data, such as H^{v}, Hⁱ, G^{v}, and Gⁱ, derived from the bus hybrid matrix and may include transforming data from the complex domain to data in the real domain. The assignment may further include determining a direct relationship between the known bus indices and the unknown bus indices and may incorporate the use of heuristics. A derivation that utilizes a matrix completion based state estimator and the hybrid matrix to solve several intermediate mathematical equations is presented in a manuscript entitled “Modified Matrix Completion-Based Detection of Stealthy Data Manipulation Attacks in Low Observable Distribution Systems”, published in the November, 2023 volume of IEEE Transactions on Smart Grid, PP(99):1-1, DOI: 10.1109/TSG.2023.3266834. The listed manuscript is incorporated by reference, in its entirety, into the current patent application, except where inconsistent with the teachings of the current patent application. The derivation concludes with the linear formulation for estimating the unknown values of voltage deviation and current at the set of nodes given by U using the known set of voltage deviations and currents at nodes K, which is given as:

$$[ \begin{matrix}2 I & 0 & {H}^{{v}^{T}} \\ 0 & 21 & {H}^{{i}^{T}} \\ {H}^{v} & {H}^{i} & 0\end{matrix} ] [ \begin{matrix}Δ {v}_{u} \\ {i}_{u} \\ w\end{matrix} ] = [ \begin{matrix}0 \\ {G}^{v} \cdot Δ {v}_{K} \\ {G}^{i} \cdot {i}_{K}\end{matrix} ] \qquad EQ . 15$$

$$[ \begin{matrix}Δ {v}_{u} \\ {i}_{u} \\ w\end{matrix} ] = J \cdot [ \begin{matrix}0 \\ Δ {v}_{K} \\ {i}_{K}\end{matrix} ] \qquad EQ . 16$$

$$wherein :$$

$$J = {[ \begin{matrix}2 I & 0 & {H}^{{v}^{⊤}} \\ 0 & 21 & {H}^{{i}^{⊤}} \\ {H}^{v} & {H}^{i} & 0\end{matrix} ]}^{- 1} [ \begin{matrix}I & 0 & 0 \\ 0 & {G}^{v} & 0 \\ 0 & 0 & {G}^{i}\end{matrix} ] \qquad EQ . 17$$

$$J = [ \begin{matrix}{J}_{Δ {v}_{u} , 0} & {J}_{Δ {v}_{u} , Δ {v}_{K}} & {J}_{Δ {v}_{u} , {i}_{K}} \\ {J}_{{i}_{u} , 0} & {J}_{{i}_{u} , Δ {v}_{K}} & {J}_{{i}_{u} , {i}_{K}} \\ {J}_{w , 0} & {J}_{w , Δ {v}_{K}} & {J}_{w , {i}_{K}}\end{matrix} ] \qquad EQ . 18$$

$$[ \begin{matrix}Δ {v}_{u} \\ {i}_{u}\end{matrix} ] = \tilde{J} \cdot [ \begin{matrix}Δ {v}_{K} \\ {i}_{K}\end{matrix} ] \qquad EQ . 19$$

$$\tilde{J} = [ \begin{matrix}{J}_{Δ {v}_{u} , Δ {v}_{K}} & {J}_{Δ {v}_{u} , {i}_{K}} \\ {J}_{{i}_{u} , Δ {v}_{K}} & {J}_{{i}_{u} , {i}_{K}}\end{matrix} ] \qquad EQ . 20$$

Referring to step 206, mean values and noise statistics of the known voltage deviation and current values and the assigned or imputed voltage deviation and current values are estimated. A noise component that is present in the known voltage deviation and current values and the assigned voltage deviation and current values is estimated as an additional noise term, so that in the following steps, the known voltage deviation and current values and the assigned voltage deviation and current values without the noise term can be used. With the diagonal co-variance matrix Σ_{K} corresponding to the noise components in measured values, the complete noise co-variance matrix, Σ, for both measured and assigned values is given as:

$$Σ = [ \begin{matrix}{Σ}_{K} & {Σ}_{K} \cdot {\tilde{J}}^{⊤} \\ \tilde{J} \cdot {Σ}_{K} & \tilde{J} \cdot {Σ}_{K} \cdot {\tilde{J}}^{⊤}\end{matrix} ] \qquad EQ . 21$$

To find the near positive definite symmetric matrix, \tilde{Σ}, for the obtained noise co-variance matrix, Σ, an algorithm not discussed in detail herein is employed. The result of applying the algorithm is:

$$[ \begin{matrix}Δ {v}_{K} \\ {i}_{K} \\ Δ {v}_{u} \\ {i}_{u}\end{matrix} ] = [ \begin{matrix}Δ {\overline{v}}_{K} \\ {\overline{i}}_{K} \\ Δ {\overline{v}}_{u} \\ {\overline{i}}_{u}\end{matrix} ] + η , η \sim N ( 0 , \tilde{Σ} ) \qquad EQ . 22$$

wherein the values of the known voltage deviation and current (Δv_{K}, i_{K}) and the assigned voltage deviation and current (Δv_{U}, i_{U}) are expressed as the sum of a plurality of mean values of the known voltage deviation and current (Δv̅_{K}, ī_{K}) with the assigned voltage deviation and current (Δv̅_{U}, ī_{U}) and the noise term n.

Referring to step 207, a residual and error statistics between a plurality of network values and a plurality of expected values are calculated using a plurality of mean values of the voltage deviation and current data at the buses for the known values and the assigned values that are calculated, or retrieved from the previous step. The network values are the known voltage deviation and current (Δv_{K}, i_{K}) and the assigned voltage deviation and current (Δv_{U}, i_{U}). The expected values are values of voltage, voltage deviation, and current for the buses and/or nodes given the impedance and/or admittance characteristics of the three phase power distribution network 100.

To carry out a chi-squared test in the next step, the mean values Δv̅, ī are required at buses given by sets K (known) and U (unknown) to calculate the residual terms. To eliminate the further estimation process, the following conditions are exploited:

$$[ \begin{matrix}Δ {\overline{v}}_{K} \\ Δ {\overline{v}}_{U}\end{matrix} ] = [ \begin{matrix}{Z}_{KK} & {Z}_{KU} \\ {Z}_{UK} & {Z}_{UU}\end{matrix} ] [ \begin{matrix}{\overline{i}}_{K} \\ {\overline{i}}_{U}\end{matrix} ] \qquad EQ . 23$$

$$[ \begin{matrix}0 \\ 0\end{matrix} ] = T [ \begin{matrix}Δ {\overline{v}}_{K} \\ {\overline{i}}_{K} \\ Δ {\overline{v}}_{u} \\ {\overline{i}}_{u}\end{matrix} ] \qquad EQ . 24$$

$$wherein :$$

$$T = [ \begin{matrix}- I & {Z}_{KK} & 0 & {Z}_{KU} \\ 0 & {Z}_{UK} & - I & {Z}_{UU}\end{matrix} ] \qquad EQ . 25$$

With this definition of T, the residuals, r, and inherently the error statistics, correspond to:

$$r = T [ \begin{matrix}Δ {v}_{K} \\ {i}_{K} \\ Δ {v}_{u \vert} \\ {i}_{u}\end{matrix} ] , r ∼ N ( 0 , Ω ) \qquad EQ . 26$$

$$wherein :$$

$$Ω = T \cdot \tilde{Σ} \cdot {T}^{⊤} \qquad EQ . 27$$

Referring to step 208, mislabeled phases in the three phase power distribution network 100 are determined using a mathematical relationship that includes a residual term and a chi squared distribution. Since residual r has a normal distribution, the residual term r^{T}Ω⁻¹r has a chi squared distribution. Thus, a chi-squared test can be applied, in which the residual term r^{T}Ω⁻¹r is compared to chi squared. For the residual term where r^{T}Ω⁻¹r>χ²_{v·p}, the presence of bad data can be suspected. p is the detection probability, which equals 0.95. v is the degree of freedom, and because there are |K| linearly independent states in the problem formulation, v equals |2K|, where K is the number of buses with sensor data. If the residual term, r^{T}Ω⁻¹r, is greater than chi squared, i.e., χ²_{v·p}, then, to identify the bus i where phase is mislabeled, consider that

$${v}_{i}^{ϕ}$$

is the complex voltage values estimated at phase φ of bus i. Since the feeders in the distribution system are short and have low X/R ratio, the phase angles of voltages at each bus is closer to the angle corresponding to its phase at the source bus. i is determined so that the following formula yields a maximum value:

$$\begin{matrix}max \\ i\end{matrix} \vert {δ}^{ϕ} - ∠ {v}_{i}^{ϕ} \vert ,$$

where δ^{φ}=0 degrees for φ, the phase label is “A”; δ^{φ}=−120 degrees for φ, the phase label is “B”; and δ^{φ}=120 degrees for φ, the phase label is “C”. If the residual term is less than or equal to chi squared, then the original phase label is assumed to be correct.

### ADDITIONAL CONSIDERATIONS

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. A method for determining one or more mislabeled phases of the voltage at one or more laterals and/or customer points in a three phase power distribution network, the method comprising:
receiving data indicating a plurality of electrical connections among components of the three phase power distribution network including a plurality of buses;
receiving a plurality of sensor data values including voltage measurements, power measurements, or both for a first portion of the buses;
converting each voltage measurement to a voltage phasor;
converting each power measurement to a current phasor;
determining a bus hybrid matrix including a bus impedance matrix and a bus admittance matrix;
assigning values of voltage, voltage deviation, and/or current to a second portion of the buses where sensor data values are unavailable utilizing data derived from the bus hybrid matrix;
calculating a residual between a plurality of network values and a plurality of expected values; and
detecting whether any phases are mislabeled in the three phase power distribution network using a mathematical relationship that includes a residual term and a chi squared term.

2. The method of claim 1, further comprising
determining mean values and noise statistics for known voltage deviation and current values and the assigned voltage deviation and current values; and
estimating a plurality of error statistics of the assigned voltage deviation and current values from the noise statistics;
wherein a matrix of the known voltage deviation and current values and the assigned voltage deviation and current values is equal to a sum of a matrix of the mean values for known voltage deviation and current values and the assigned voltage deviation and current values and the noise component.

3. The method of claim 2, wherein the known voltage deviation and current values are derived from the received sensor data values.

4. The method of claim 1, wherein the bus impedance matrix includes a plurality of known impedances and a plurality of unknown impedances.

5. The method of claim 1, wherein the bus admittance matrix includes a plurality of known admittances and a plurality of unknown admittances.

6. The method of claim 1, wherein the residual term is derived from the residual and determining correct labels includes determining whether the residual term is greater than the chi squared term.

7. The method of claim 6, wherein it is determined that at least one phase is mislabeled (Original) if the residual term is greater than the chi squared term.

8. A computing device for determining one or more mislabeled phases of the voltage at one or more laterals and/or customer points in a three phase power distribution network, the computing device comprising:
a processing element configured or programmed to:
receive data indicating a plurality of electrical connections among components of the three phase power distribution network including a plurality of buses;
receive a plurality of sensor data values including voltage measurements, power measurements, or both for a first portion of the buses;
convert each voltage measurement to a voltage phasor;
convert each power measurement to a current phasor;
determine a bus hybrid matrix including a bus impedance matrix and a bus admittance matrix;
assign values of voltage, voltage deviation, and/or current to a second portion of the buses where sensor data values are unavailable utilizing data derived from the bus hybrid matrix;
calculate a residual between a plurality of network values and a plurality of expected values; and
detect whether any phases are mislabeled in the three phase power distribution network using a mathematical relationship that includes a residual term and a chi squared term.

9. The computing device of claim 1, wherein the processing element is further configured or programmed to:
determine mean values and noise statistics for known voltage deviation and current values and the assigned voltage deviation and current values; and
estimate a plurality of error statistics of the assigned voltage deviation and current values from the noise statistics;
wherein a matrix of the known voltage deviation and current values and the assigned voltage deviation and current values is equal to a sum of a matrix of the mean values for known voltage deviation and current values and the assigned voltage deviation and current values and the noise component.

10. The computing device of claim 9, wherein the known voltage deviation and current values are derived from the received sensor data values.

11. The computing device of claim 8, wherein the bus impedance matrix includes a plurality of known impedances and a plurality of unknown impedances.

12. The computing device of claim 8, wherein the bus admittance matrix includes a plurality of known admittances and a plurality of unknown admittances.

13. The computing device of claim 8, wherein the residual term is derived from the residual and determining correct labels includes determining whether the residual term is greater than the chi squared term.

14. The computing device of claim 13, wherein it is determined that at least one phase is mislabeled if the residual term is greater than the chi squared term.

15. A non-transitory computer readable medium having stored thereon software instructions for determining one or more mislabeled phases of the voltage at one or more laterals and/or customer points in a three phase power distribution network that, when executed by a processing element, cause the processing element to:
receive data indicating a plurality of electrical connections among components of the three phase power distribution network including a plurality of buses;
receive a plurality of sensor data values including voltage measurements, power measurements, or both for a first portion of the buses;
convert each voltage measurement to a voltage phasor;
convert each power measurement to a current phasor;
determine a bus hybrid matrix including a bus impedance matrix and a bus admittance matrix;
assign values of voltage, voltage deviation, and/or current to a second portion of the buses where sensor data values are unavailable utilizing data derived from the bus hybrid matrix;
calculate a residual between a plurality of network values and a plurality of expected values; and
detect whether any phases are mislabeled in the three phase power distribution network using a mathematical relationship that includes a residual term and a chi squared term.

16. The non-transitory computer readable medium of claim 15, wherein the processing element is further caused to:
determine mean values and noise statistics for known voltage deviation and current values and the assigned voltage deviation and current values; and
estimate a plurality of error statistics of the assigned voltage deviation and current values from the noise statistics;
wherein a matrix of the known voltage deviation and current values and the assigned voltage deviation and current values is equal to a sum of a matrix of the mean values for known voltage deviation and current values and the assigned voltage deviation and current values and the noise component.

17. The non-transitory computer readable medium of claim 16, wherein the known voltage deviation and current values are derived from the received sensor data values.

18. The non-transitory computer readable medium of claim 15, wherein the bus impedance matrix includes a plurality of known impedances and a plurality of unknown impedances.

19. The non-transitory computer readable medium of claim 15, wherein the bus admittance matrix includes a plurality of known admittances and a plurality of unknown admittances.

20. The non-transitory computer readable medium of claim 15, wherein the residual term is derived from the residual and determining correct labels includes determining whether the residual term is greater than the chi squared term and if so, then at least one phase is mislabeled.
